(19) United States
(12) Patent Application Publication
(10) Pub. No.: US 2007/0075441 A1
(43) Pub. Date: Apr. 5, 2007

(54) CHIP PACKAGE STRUCTURE

(75) Inventors: Cheng-Yin Lee, Tainan City (TW); Yung-Li Lu, Kaohsiung County (TW); Po-Ching Su, Kaohsiung City (TW)

Correspondence Address: J C PATENTS, INC., 4 VENTURE, SUITE 250, IRVINE, CA, 92618, US

(73) Assignee: Advanced Semiconductor Engineering, Inc., Kaohsiung (TW)

(21) Appl. No.: 11/463,404

(22) Filed: Aug. 9, 2006

(30) Foreign Application Priority Data
Aug. 18, 2005 (TW) 94128154

(51) Int. Cl. H01L 23/28

(52) U.S. Cl. 257/787; 257/E23.116

(57) ABSTRACT

A chip package structure including a chip, a carrier, a plurality of bonding wires and a molding compound is provided. The chip has an active surface, a back surface opposite to the active surface, a plurality of side surfaces, and a plurality of flash-preventing surfaces located between the active surface and the side surfaces. The carrier is connected to the back surface of the chip to carry the chip. The chip is electrically connected to the carrier via the bonding wires. The molding compound is disposed on the carrier and encapsulates the bonding wires, a portion of the active surface, the side surfaces, and at least a portion of the flash-preventing surfaces. The flash-preventing surfaces prevent excess molding compound from contaminating the active surface of the chip.

### CROSS-REFERENCE TO RELATED APPLICATION

This application claims the priority benefit of Taiwan application serial no. 94128154, filed on Aug. 18, 2005. All disclosure of the Taiwan application is incorporated herein by reference.

### BACKGROUND OF THE INVENTION

1. Field of the Invention

The present invention relates to a chip package structure, and more particularly, to a chip package structure with a flash-preventing surface.

2. Description of Related Art

In the semiconductor manufacturing industry, the production of integrated circuits (IC) is mainly divided into three major stages: wafer production stage, integrated circuit (IC) fabrication stage and integrated circuit (IC) packaging stage. A bare die is produced after performing a series of processes including, for example, wafer epitaxy, integrated circuit design, photolithography/etch process and wafer sawing. Each of the bare dies is cut out from a wafer and then electrically connected to an external signal via contacts on the bare die, a substrate, and bonding wires connected between the contacts and the substrate. Afterwards, the bare die is encapsulated using a molding compound to form a package. The packaging process prevents moisture, heat and noise from affecting the die and provides a medium for connecting with an external circuit.

FIG. 1 is a perspective view of a conventional chip package structure. As shown in FIG. 1, a conventional chip package structure 100 includes a chip 110, a substrate 120, a plurality of bonding wires 130 and a molding compound 140. The chip 110 has an active surface 112, a back surface 114 opposite to the active surface 112, and a plurality of side surfaces 116. In addition, the substrate 120 is connected to the back surface 114 of the chip 110 to carry the chip 110. The chip 110 is electrically connected to the substrate 120 via the bonding wires 130. The molding compound 140 is disposed on the substrate 120 and encapsulates the bonding wires 130, a portion of the active surface 112, and the side surfaces 116.

FIG. 2 is a schematic cross-sectional view of the chip package structure in FIG. 1 within a mold during a molding process. As shown in FIG. 2, in the process of forming the conventional chip package structure 100 by molding, the shape of the mold M and the corresponding shape of the chip 110 are substantially identical. Thus, when the partially melted molding compound 140 is injected into the mold M, the molding compound may overflow into the active surface 112 of the chip 110 and contaminate the active surface of the chip 110 (as shown in FIG. 1). Accordingly, one ordinary skilled in the art needs to improve the current method of fabricating the conventional chip package structure 100.

### SUMMARY OF THE INVENTION

Accordingly, the present invention is directed to provide a chip package structure having flash-preventing surfaces to prevent molding compound from contaminating an active surface of a chip.

As embodied and broadly described herein, the invention provides a chip package structure. The chip package structure includes a chip, a carrier, a plurality of bonding wires and a molding compound. The chip has an active surface, a back surface opposite to the active surface, a plurality of side surfaces, and a plurality of flash-preventing surfaces located between the active surface and the side surfaces. The carrier is connected to the back surface of the chip to carry the chip. The chip is electrically connected to the carrier via the bonding wires. The molding compound is disposed on the carrier and encapsulates the bonding wires, a portion of the active surface, the side surfaces, and at least a portion of the flash-preventing surfaces.

According to one preferred embodiment of the present invention, the foregoing chip includes, for example, a charge-coupled device, a complementary metal-oxide-semiconductor (CMOS) image sensor, a fingerprint identification device or a photo-diode.

According to one preferred embodiment of the present invention, the foregoing flash-preventing surfaces is slant surfaces with respect to the active surface.

According to one preferred embodiment of the present invention, the foregoing flash-preventing surfaces includes, for example, a first surface and a second surface. The first surface connects with the active surface and the second surface connects between the first surface and the side surfaces. In addition, the first surface is substantially perpendicular to the active surface and the second surface is substantially parallel to the active surface.

Since the flash-preventing surfaces in the chip package structure of the present invention can be formed in a wafer cutting process using a specially designed wafer cutting knife, there is no need to provide additional processing steps. Furthermore, the flash-preventing surface formed in the chip package structure is quite effective in preventing flash contamination.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a conventional chip package structure.

FIG. 2 is a schematic cross-sectional view of the chip package structure in FIG. 1 within a set of molds during a molding process.

FIG. 3 is a perspective view of a chip package structure according to a first embodiment of the present invention.

FIGS. 4A and 4B are schematic cross-sectional views of the chip package structure in FIG. 2 undergoing a wafer cutting process.

FIG. 5 is a schematic cross-sectional view of the chip package structure in FIG. 2 undergoing a molding process.

FIG. 6 is a schematic cross-sectional view of a chip package structure according to a second embodiment of the present invention.

FIGS. 7A and 7B are schematic cross-sectional views of the chip package structure in FIG. 6 undergoing a wafer cutting process.

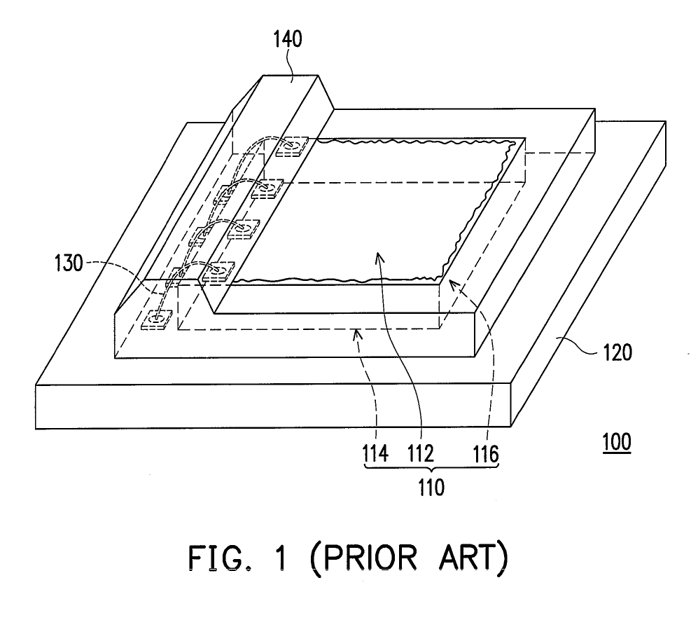

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

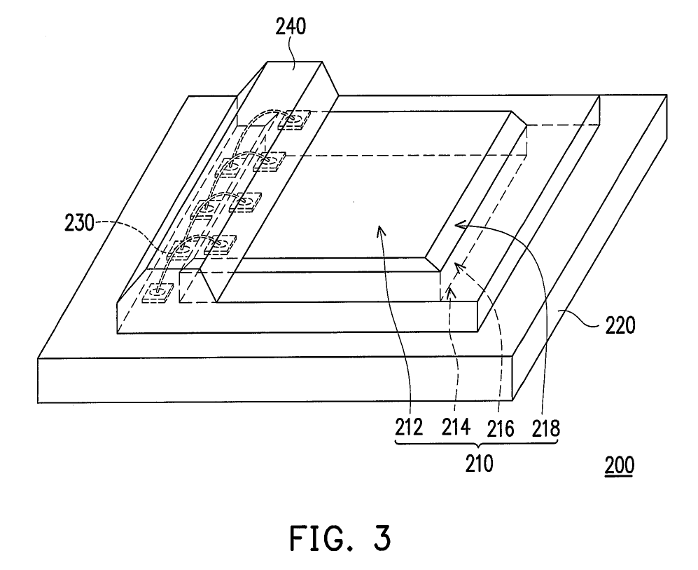

FIG. 3 is a perspective view of a chip package structure according to a first embodiment of the present invention. As shown in FIG. 3, the chip package structure 200 in the present embodiment includes a chip 210, a carrier 220, a plurality of bonding wires 230, and a molding compound 240. The chip 210 has an active surface 212, a back surface 214 opposite to the active surface 212, a plurality of side surfaces 216, and a plurality of flash-preventing surfaces 218. The flash-preventing surfaces 218 are located between the active surface 212 and the side surfaces 216. The carrier 220 is connected to the back surface 214 of the chip 210 to carry the chip 210. The chip 210 is electrically connected to the carrier 220 via the bonding wires 230. The molding compound 240 is disposed on the carrier 220 and encapsulates the bonding wires 230, a portion of the active surface 212, the side surfaces 216, and at least a portion of the flash-preventing surfaces 218.

The chip 210 can be a charge-coupled device, a complementary metal-oxide-semiconductor (CMOS) image sensor, a fingerprint identification device or a photodiode. The functions of the chip 210 include receiving an external light signal and converting the signal into an electrical signal for further processing. The carrier 220 can be a substrate (e.g. a plastic, ceramic, or silicon substrate with circuitry formed therein). The molding compound 240 protects the bonding wires 230 against effects caused by external moisture, heat and noise. Furthermore, the molding compound 240 also supports the bonding wires 230 so as to prevent short circuit between two adjacent bonding wires 230 and provides a shape suitable for holding. It should be noted that the flash-preventing surfaces 218 of the chip 210 in the present embodiment are slant surfaces with respect to the active surface 212.

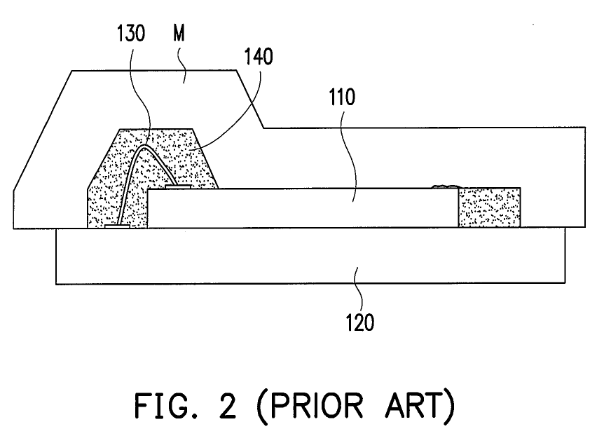

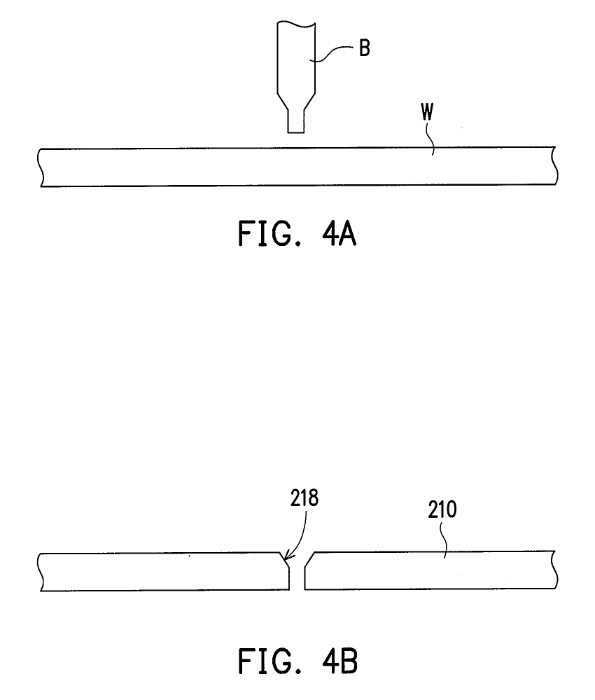

In the following, the wafer cutting and molding process for fabricating the chip package structure 200 of the present embodiment is explained in detail. FIGS. 4A and 4B are schematic cross-sectional views of the chip package structure in FIG. 2 undergoing a wafer cutting process. When a wafer manufacturer delivers wafers W with a plurality of chips fabricated thereon to a packaging factory, all the back-end processes to fabricate the semiconductor device are carried out inside the packaging factory. First, the chips 210 in each of the wafers W must be cut and detached during a wafer sawing process. In order to form slant flash-preventing surfaces 218, a special cutting knife B is used in the wafer sawing process to produce a plurality of chips 210 each having slant flash-preventing surfaces 218.

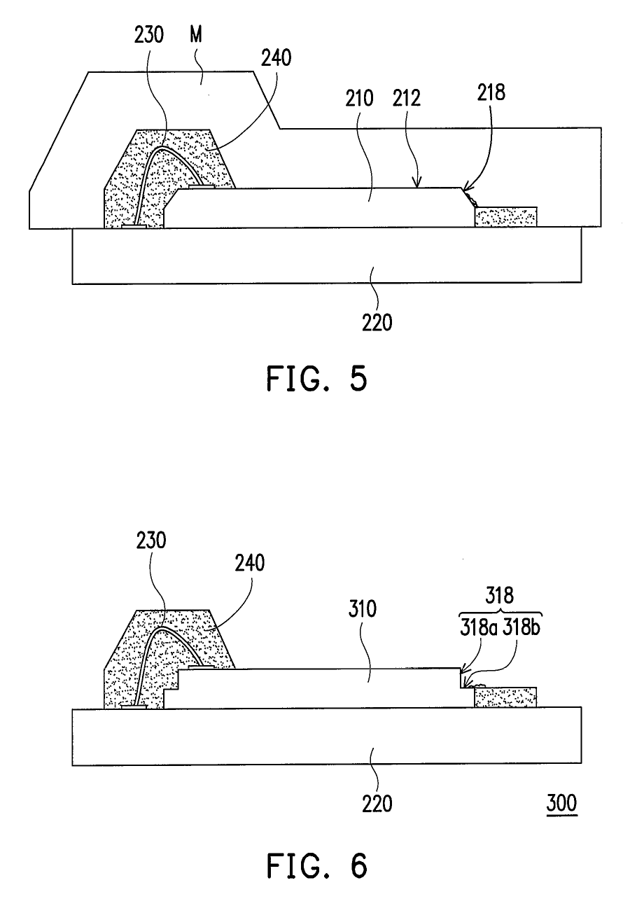

After cutting out the chip 210, a die bonding process and a wire bonding process are performed followed by a molding process. FIG. 5 is a schematic cross-sectional view of the chip package structure in FIG. 2 undergoing a molding process. As shown in FIG. 5, a mold M is disposed over the carrier 220 to cover the chip 210 and the bonding wires 230. Then, a partially melted molding compound 240 (for example, a resin) is injected into the mold M and the height of the molding compound 240 is carefully controlled. Due to the presence of the flash-preventing surfaces 218 in the chip 210, the flash (overflow) generated by the injected molding compound 240 in the molding process is confined to the flash-preventing surfaces 218 and will not flow further to contaminate the active surface 212. Accordingly, aside from encapsulating the bonding wires 230 and covering a portion of the active surface 212, the molding compound 240 will not produce flash that contaminates other areas.

### Second Embodiment

FIG. 6 is a schematic cross-sectional view of a chip package structure according to a second embodiment of the present invention. The main difference between the second embodiment and the first embodiment is that the chip 310 in the second embodiment has flash-preventing surfaces 318 in the shape of a staircase. As shown in FIG. 6, the flash-preventing surface 318 includes, for example, a first surface 318 and a second surface 318b. The first surface 318a connects with the active surface 312 and the second surface 318b connects between the first surface 318a and the side surfaces 316. In addition, the first surface 318a is substantially perpendicular to the active surface 312 while the second surface 318b is substantially parallel to the active surface 312.

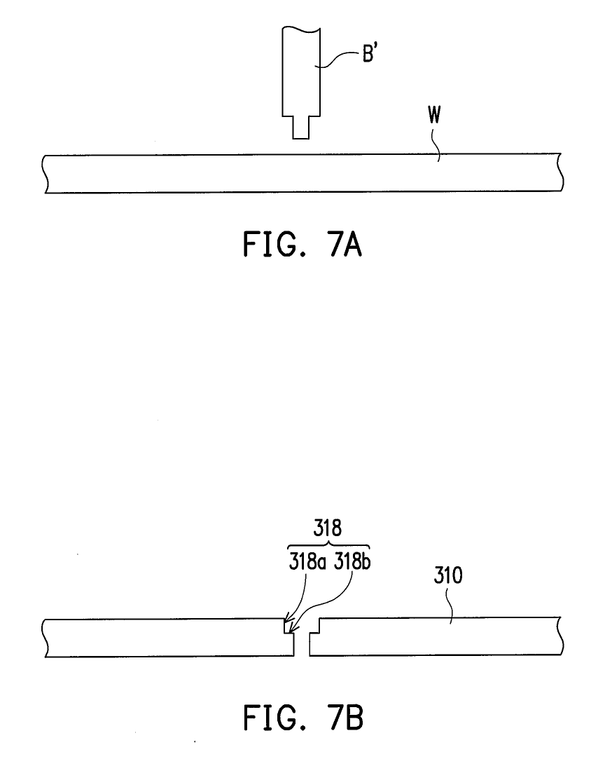

FIGS. 7A and 7B are schematic cross-sectional views of the chip package structure in FIG. 6 undergoing a wafer cutting process. To perform a wafer cutting process of the chip package structure 300 in the second embodiment, the shape of the cutting knife B′ has corresponding changes so that flash-preventing surfaces having the aforementioned staircase shape are formed. It should be noted that the number of steps in the staircase and the profile of the steps in the flash-preventing surfaces 318 can be changed as long as the change does not affect the design of the flash-preventing surfaces 318 to preventing the contamination of the active surface 312. Therefore, the present embodiment serves as an example only and should not be used to limit the scope of the present invention. Since the molding process is substantially identical to that of the first embodiment, a detailed description is omitted.

In summary, the chip package structure in the present invention has the following advantages:

1. Since the flash-preventing surfaces are formed in a wafer cutting process using a specially designed wafer cutting knife, there is no need to provide additional processing steps.

2. Through the flash-preventing surfaces in the chip package structure, contamination of the active surface of the chip by flash in the molding process is significantly diminished.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package structure, comprising:
a chip, having an active surface, a back surface opposite to the active surface, a plurality of side surfaces, and a plurality of flash-preventing surfaces located between the active surface and the side surfaces;
a carrier, connected to the back surface of the chip to carry the chip;
a plurality of bonding wires electrically connecting the chip and the carrier; and
a molding compound disposed on the carrier, wherein the molding compound encapsulates the bonding wires, a portion of the active surface, the side surfaces, and at least a portion of the flash-preventing surfaces.

2. The chip package structure of claim 1, wherein the chip comprises a charge-coupled device, a complementary metal-oxide-semiconductor (CMOS) image sensor, a fingerprint identification device or a photodiode.

3. The chip package structure of claim 1, wherein the flash-preventing surfaces are slant surfaces with respect to the active surface.

4. The chip package structure of claim 1, wherein the flash-preventing surface comprises a first surface and a second surface, the first surface connects with the active surface and the second surface connects between the first surface and the side surfaces.

5. The chip package structure of claim 4, wherein the first surface is perpendicular to the active surface and the second surface is parallel to the active surface.
